(19) United States
(12) Patent Application Publication
(10) Pub. No.: US 2006/0120183 A1
(43) Pub. Date: Jun. 8, 2006

(54) System and method for monitoring active device by restoring symbol table in duplexing system

(75) Inventor: Won-Ki Hong, Seoul (KR)

Correspondence Address: JONATHAN Y. KANG, ESQ.;LEE, HONG, DEGERMAN, KANG & SCHMADEKA, P.C., 14th Floor, 801 S. Figueros Street, Los Angeles, CA, 90017-5554, US

(73) Assignee: LG-Nortel Co., Ltd.

(21) Appl. No.: 11/281,323

(22) Filed: Nov. 16, 2005

(30) Foreign Application Priority Data
Nov. 17, 2004 (KR) 10-2004-0094106

(51) Int. Cl. G11C 7/00

(52) U.S. Cl. 365/194

(57) ABSTRACT

A system and method is provided for a standby device in a duplexing system of a mobile communication system to monitor an active device by restoring a symbol table having an error. When the active device is initialized, symbol table related information is stored. When a user command for monitoring the active device is transmitted from a standby device, the active device determines that the symbol table has an error, restores the symbol table by using the previously stored symbol table related information, performs the user command using the restored symbol table and transmits the results of performing the command to the standby device.

### CROSS-REFERENCE TO RELATED APPLICATIONS

Pursuant to 35 U.S.C. § 19(a), this application claims the benefit of earlier filing date and right of priority to Korean Application No. 94106/2004, filed on Nov. 17, 2004, the contents of which is hereby incorporated by reference herein in its entirety.

### BACKGROUND OF THE INVENTION

1. Field of the Invention

The present invention relates to a mobile communication system having a duplexing system and, more particularly, to a system and method for a standby device to monitor an active device in a duplexing system of a mobile communication system such that the active device determines that there is an error in its symbol table, restores the symbol table and performs a command received from the standby device.

2. Description of the Related Art

In general, a device such as a data exchange device (hereafter referred to as an ‘exchange’) used in a mobile communication system has a duplex structure including an active device and a standby device and is operated such as to ensure stable data exchange even if a failure occurs. Specifically, in an asynchronous exchange to which the present invention can be applied, the standby device is not actually operated under normal circumstances. Instead, the standby device sequentially starts its operation to take over for the active device upon a failure in the active device, thereby enabling stable data exchange to be achieved.

A typical duplexing system of a mobile communication system includes an active device for performing a main operation and a standby device connected with the active device and operated as an auxiliary device. If a console of the active device is in an abnormal state, the standby device receives a command from a user for monitoring the active device and transmits the command to the active device. The active device then performs the user command and transmits results of performing the command to the standby device. The standby device can then display the performance results to the user.

In a method for monitoring the active device through the standby device in a conventional duplex system of a mobile communication system, when an error or defect occurs in hardware related to a console driver in the active device or in the active device itself, the active device can be controlled by using the standby device. When a user command required for monitoring and debugging the error is received from the standby device, the active device searches its symbol table to parse the user command and then performs the user command.

In other words, in order for a standby shell, for example, a software program routine of the active device, to perform the user command, the standby shell searches the position or location of the user command with reference to the symbol table managed by an Operating System (OS). However, if the symbol table has an error, for example, due to a different (external) software program such as a user program, the standby shell of the active device cannot properly perform the user command.

Therefore, the method for a standby device to monitor an active device in a conventional duplexing system of a mobile communication system has a disadvantage when the symbol table required for performing a user command contains an error. If this occurs, the user command cannot be performed and the active device cannot be properly monitored.

Therefore, there is a need for a system and method for a standby device to monitor an active device in a duplexing system of a mobile communication system that facilitates performing a user command even when a symbol table necessary for the active device to perform the command has an error. The present invention addresses these and other needs.

### SUMMARY OF THE INVENTION

Features and advantages of the invention will be set forth in the description which follows, and in part will be apparent from the description, or may be learned by practice of the invention. The objectives and other advantages of the invention will be realized and attained by the structure particularly pointed out in the written description and claims as well as the appended drawings.

The invention is directed to provide a system and method for a standby device to monitor an active device in a duplexing system of a mobile communication system. If the active device determines that there is an error in its symbol table, the active device restores the symbol table in order to perform a command received from the standby device.

Therefore, one object of the present invention is to provide a method for restoring a symbol table in a duplexing system capable of allowing an active device to store symbol table related information when initialized, determine if an error occurs in the symbol table and recover from the error in the symbol table by using the previously stored symbol table related information.

Another object of the present invention is to provide a method for a standby device to monitor an active device such that when an error occurs in a symbol table of the active device, the active device restores the symbol table and performs a user command received from the standby device by using the restored symbol table.

To achieve at least the above objects in whole or in part, there is provided a method for a standby device to monitor an active device in a duplexing system of a mobile communication system, including: the active device receiving a user command transmitted from the standby device; the active device determining if an error exists in a symbol table used by the active device to process the user command; and the active device restoring the symbol table using previously stored symbol table related information.

To achieve at least these advantages in whole or in part, there is further provided a method for a standby device to monitor an active device in a duplexing system of a mobile communication system, including: the standby device transmitting a user command to the active device; the active device determining if an error exists in a symbol table; the active device restoring the symbol table using previously stored symbol table related information; the active device performing the user command by using the symbol table; and the active device transmitting a result of performing the user command.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims. It is to be understood that both the foregoing general description and the following detailed description of the present invention are exemplary and explanatory and are intended to provide further explanation of the invention as claimed.

These and other embodiments will also become readily apparent to those skilled in the art from the following detailed description of the embodiments having reference to the attached figures, the invention not being limited to any particular embodiments disclosed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. Features, elements, and aspects of the invention that are referenced by the same numerals in different figures represent the same, equivalent, or similar features, elements, or aspects in accordance with one or more embodiments.

FIG. 1 is a schematic block diagram illustrating an exemplary construction of a duplexing system of a mobile communication system in accordance with the present invention.

FIGS. 2A and 2B are flow charts illustrating an exemplary method for a standby device to monitor an active device that can restore a symbol table in accordance with the present invention.

FIG. 3 illustrates an exemplary structure of a memory of the active device of the present invention.

### DETAILED DESCRIPTION OF THE PREFERRED EMBODIMENTS

The present invention relates to a system and method for a standby device to monitor an active device in a duplexing system of a mobile communication system such that the active device determines that there is an error in its symbol table, restores the symbol table and performs a command received from the standby device. Although the present invention is illustrated with respect to a mobile communication system, it is contemplated that the present invention may be utilized anytime it is desired to enable a standby device to monitor an active device such that the active device may perform a command from the standby device even when a reference table used to perform the command has an error.

In the present invention, an active device stores symbol table related information when it is initialized and, when a user command is received from a standby device, the active device determines whether the symbol table has an error. If the symbol table has an error, the active device restores the error by using the previously stored symbol table related information and performs the user command by using the recovered symbol table. The active device then transmits the results of performing the user command to the standby device.

In a duplexing system of a mobile communication system of the present invention in which a standby device monitors an active device, the active device my detect any errors generated in a symbol table and may restore the symbol table if needed such that user commands may be performed even when an error exists in the symbol table, for example, due to external reasons such as different software, thereby allowing the active device to be properly monitored and debugged.

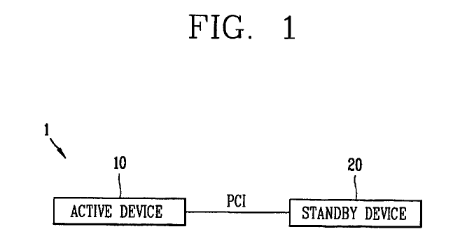

An embodiment of the present invention will now be described with reference to the accompanying drawings. FIG. 1 is a schematic block diagram illustrating the construction of an exemplary duplexing system of a mobile communication system in accordance with the present invention.

The duplexing system 1 may include an active device 10 and a standby device 20. The active device 10 is adapted to store symbol table related information when initialized, restore a symbol table containing an error by using the symbol table related information, and perform a received user command. The standby device 20 is adapted to transmit a user command to the active device 10 and to monitor the active device 10 by receiving results of the active device performing the user command. The active device 10 and the standby device 20 can be connected through a fast Ethernet connection or by a PCI (Peripheral Communication Interface).

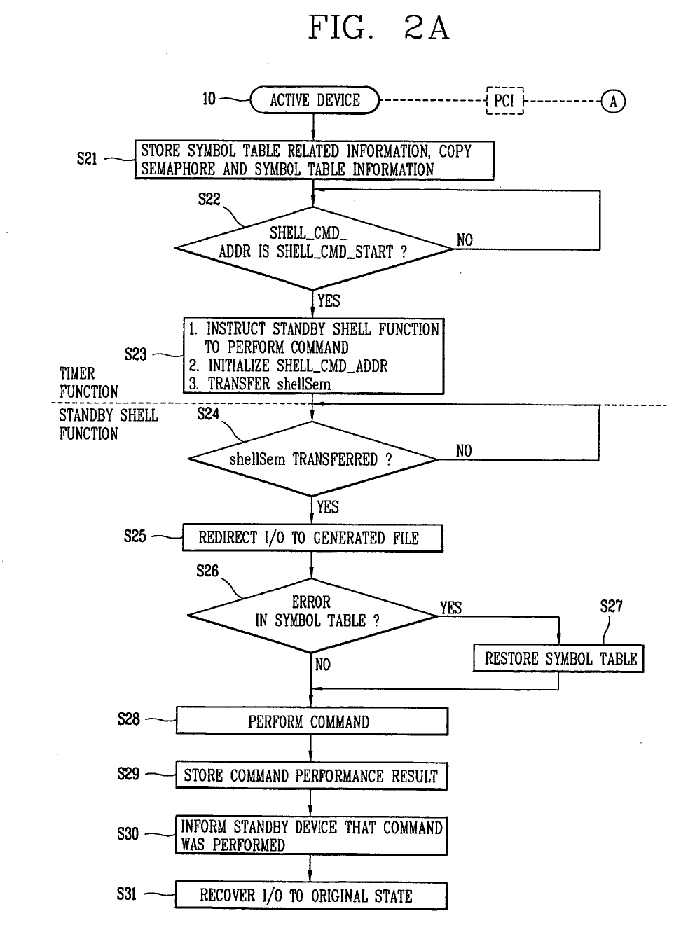

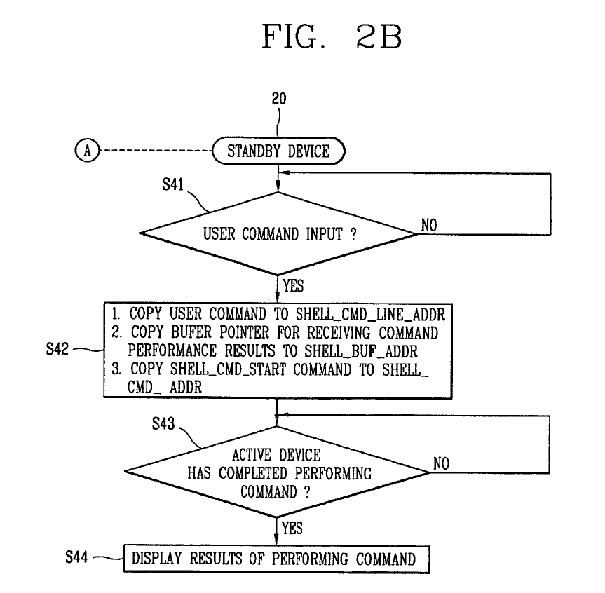

The method for the standby device to monitor the active device in the duplexing system of the mobile communication system constructed as described above will be explained in detail with reference to FIGS. 2A and 2B. FIGS. 2A and 2B are flow charts illustrating an exemplary method of the present invention for monitoring an active device by restoring a symbol table. As illustrated In FIGS. 2A and 2B, when hardware or software related to a console of the active device 10 is defective or contains errors, a standby shell, for example, a software routine of the active device 10, performs a user command(s) transmitted from the standby device 20 and transmits corresponding results of performing the command to the standby device 20, thereby enabling the standby device 20 to monitor the active device 10.

When the active device 10 is initially operated, it stores (copies) symbol table related information, generates and/or initializes a semaphore (shellSem) for communication between a timer function for receiving a command from the standby device 20 and a standby shell function for processing the command, and initializes specific memory addresses set for communication with the standby device 20 (step S21).

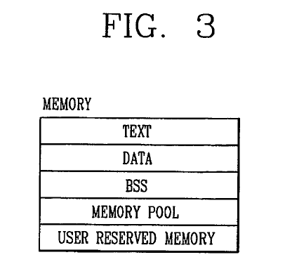

FIG. 3 illustrates a structure of an exemplary memory of the active device in accordance with the present invention. As illustrated in FIG. 3, the memory includes a text region or section used for storing a program code, a data region used for storing an initialized global variable, a BSS region for storing non-initialized data, a memory pool region allocated by a program according to each user, such as a ‘malloc’ mathematical function, and a user reserved memory region for user reserved operations. The symbol table related information required for performing a user command is stored in the BSS region and includes an address of a symbol table and semaphore related information of the symbol table.

The specific memory addresses may include a shell command address (SHELL_CMD_ADDR) indicating whether there is a command, a shell command line address (SHELL_CMD_LINE_ADDR) indicating a command to be performed, and a shell buffer address (SHELL_BUF_ADDR) storing command performance results. The shell command address, the shell command line address and the shell buffer address can be stored in the user reserved memory region of the memory. The active device 10 has a standby shell function for performing the user command received from the standby device and a timer function for periodically detecting whether there is a user command.

The symbol table related information is stored by the standby shell function of the active device 10. Specifically, when the active device 10 is initially operated, the standby shell function copies the symbol table related information stored in the BSS region into the standby shell function as local data.

The shell command address is initialized by the timer function and the shell command line address and the shell buffer address are initialized by the standby shell function. The specific memory addresses set for communication with the standby device 20 are initialized by the standby shell function. After the initialization operation, the timer function checks a value of the shell command address periodically to determine whether to instruct the standby shell function to perform a command (S22).

At the same time, when the standby device 20 is connected with the active device 10, the standby device 20 can check whether a user inputs a command for monitoring the active device 10 (S41). When a user command is input, the standby device 20 copies the user command into the shell command line address (SHELL_CMD_LINE_ADDR), copies a buffer pointer for receiving command performance results into the shell buffer address (SHELL_BUF_ADDR) of the active device 10, and copies a command (SHELL_CMD_START) for instructing the start of performing the command into the shell command address (SHELL_CMD_ADDR) (step S42). Thereafter, the standby device 20 waits for the active device 10 to complete performing the command (step S43).

If the value of the shell command address is determined to be a shell command start (SHELL_CMD_START) for instructing the start of performing the command (S22), the timer function of the active device 10 instructs the standby shell function to perform the command (step S23). At this time, the timer function initializes the shell command address (SHELL_CMD_ADDR) so that a next command can be stored and transfers the shell semaphone (shellSem) to the standby shell function.

Then, the standby shell function of the active device 10 checks whether the shell semaphore (shellSem) has been transferred (step S24). When the shell semaphone (shellSem) has been obtained, the standby shell function generates a file for storing the command performance results in a RAM disk and re-directs all of its input/output to the file (S25).

The standby shell function determines whether the symbol table has an error by comparing the previously stored symbol table related information with the symbol table (S26). If the symbol table has an error, the standby shell function restores the symbol table by using the previously stored symbol table related information (S27).

For example, in order to use the symbol table, the shell semaphore must be transmitted to a certain function and the shell semaphore must be returned when the certain function completes its use of the symbol table. However, if the transferred shell semaphore is not normally returned, the standby shell function discovers the shell semaphore and normally returns it. The standby shell function can store the contents of the error generated in the symbol table and the restored content of the symbol table in the file. The content of the error generated in the symbol table and the restored content of the symbol table can also be transferred to the standby device such that it may be displayed to the user.

The standby shell function of the active device 10 parses the user command in the shell command address (SHELL_CMD_ADDR) with reference to the restored symbol table and performs the command (S28). The results of performing the user command are stored in the file (S29).

The standby shell function of the active device 10 copies the performance results stored in the file into a buffer pointer stored in the shell buffer address (SHELL_BUF_ADDR) of the standby device 20, thereby informing the standby device that the user command has been performed (S30). The standby shell function of the active device 10 recovers all of its inputs and outputs, which have been redirected to the file, to their original state (step S31). When the active device 10 completes performing the user command, the standby device 20 displays the results of performing the user command stored in its buffer pointer (step S44).

Accordingly, in the method of the present invention, when the symbol table for performing a user command transmitted from the standby device has an error, the symbol table is restored so that the active device can perform the user command with reference to the restored symbol table and the standby device can be provided with the results of the active device performing the command. It can be understood that the methods and procedures of the present invention can be performed by software, hardware, and/or any combination thereof. Those skilled in the art can understand that such methods and codes can be stored in memory or storage and are executable by a processor.

The present invention provides a system used in mobile communications. The system includes an active device connected with a standby device. The active device has a memory and a processor adapted to perform various main tasks using an operating system and a symbol table managed by the operating system. The standby device has a memory and a processor adapted to perform various auxiliary tasks and to monitor the active device. The active device and the standby device cooperate to allow the active device to store symbol table related information when initialized, to check whether an error occurs in the symbol table, and to recover from an error in the symbol table by using previously stored symbol table related information.

The active device and the standby device can be connected via an Ethernet connection or a Peripheral Communication Interface. The active device also employs a standby shell software routine to perform user commands sent from the standby device and to transmit corresponding performance results to the standby device, thereby allowing the standby device to monitor the active device when hardware or software related to a console of the active device is defective or contains errors.

As so far described, the method for a standby device to monitor an active device in accordance with the present invention has several advantages. First, the active device can store information related to the symbol table when initialized, determine whether the symbol table has an error, and restore the symbol table by using the previously stored symbol table related information. Second, when the symbol table has an error, the active device restores the symbol table and performs a user command received from the standby device, thereby allowing the standby device to monitor the active device. Third, when the console of the active device is not operational, for example, is defective or has an error, information required for debugging can be obtained by using the standby shell. Fourth, since the symbol table for processing the user command is provided no matter which operating system (OS) the duplexing system uses, as long as the information indicating a position of the symbol table used in the OS is obtained, the standby shell can be used.

The foregoing embodiments and advantages are merely exemplary and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. In the claims, means-plus-function clauses are intended to cover the structure described herein as performing the recited function and not only structural equivalents but also equivalent structures.

What is claimed is:

1. A method for ensuring stable exchange of data in a mobile communication system having a duplexing system, the method comprising:
a standby device transmitting a user command to an active device;
the active device determining if an error exists in a symbol table to be used by the active device to process the user command; and
the active device restoring the symbol table using previously stored symbol table related information if an error exists in the symbol table.

2. The method of claim 1, wherein the symbol table related information is stored when the active device is initialized.

3. The method of claim 1, wherein the symbol table related information comprises an address of the symbol table and semaphore related information of the symbol table.

4. The method of claim 1, wherein the symbol table related information is stored as local data in a standby shell function.

5. The method of claim 1, wherein the user command comprises a command for monitoring a state of the active device.

6. The method of claim 1, further comprising:
the active device performing the command using the symbol table; and
the active device transmitting a result of performing the command to the standby device.

7. The method of claim 6, further comprising:
the active device storing the symbol table related information when the active device is initialized;
the active device generating and initializing a semaphore for communication between a timer function and a standby shell function, the timer function for receiving the command from the standby device and the standby shell function for processing the command; and
the active device initializing specific memory addresses set for communication with the standby device.

8. The method of claim 7, wherein the specific memory addresses comprise:
a shell command address indicating that a command is to be performed;
a shell command line address for indicating the command to be performed; and
a shell buffer address for storing the result of performing the command.

9. The method of claim 6, wherein determining if an error exists in the symbol table comprises comparing the symbol table to the previously stored symbol table related information.

10. The method of claim 6, wherein the result of performing the command comprises the content of an error determined in the symbol table, a cause of the determined error and the restored content of the symbol table.

11. The method of claim 6, wherein the symbol table related information comprises an address of the symbol table and semaphore related information of the symbol table.

12. The method of claim 6, wherein the symbol table related information is stored as local data in a standby shell of the active device.

13. The method of claim 6, wherein the user command comprises a command for monitoring a state of the active device.

14. The method of claim 6, wherein restoring the symbol table and performing the command are performed by a standby shell function of the active device.

15. The method of claim 6, wherein transmitting the user command comprises:
copying an indicator of a start of performing the command into a first address of the memory;
copying the user command into a second address of a memory in the active device; and
storing a buffer pointer for receiving the result of performing the command in a third address of the memory.

16. The method of claim 15, wherein the first address is a shell command address, the second address is a shell command line address and the third address is a shell buffer address.

17. The method of claim 15, wherein a timer function of the active device periodically checks the first address and detects the indicator.

18. A system for ensuring stable exchange of data in mobile communications, comprising:
an active device comprising a memory and a processor adapted to perform various main tasks using an operating system and a symbol table managed by the operating system; and
a standby device comprising a memory and a processor adapted to perform various auxiliary tasks, the standby device connected to the active device, and further adapted to monitor the active device,
wherein the active device and the standby device cooperate to enable the active device to store symbol table related information when the active device initialized, determine if an error exists in the symbol table and restore the symbol table using the stored symbol table related information if an error exists in the symbol table.

19. The system of claim 18, wherein the active device and the standby device are connected via one of an Ethernet connection and a Peripheral Communication Interface.

20. The system of claim 18, wherein the active device further comprises a standby shell software routine, the standby shell software routing adapted to perform user commands received from the standby device and to transmit corresponding performance results to the standby device to facilitate the standby device monitoring the active device.
